(19) United States
(12) Patent Application Publication
(10) Pub. No.: US 2010/0289684 A1
(43) Pub. Date: Nov. 18, 2010

(54) ANALOG-DIGITAL CONVERTER CIRCUIT AND ANALOG-DIGITAL CONVERSION METHOD

(75) Inventor: Mamoru IKEDA, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/776,467

(22) Filed: May 10, 2010

(30) Foreign Application Priority Data
May 18, 2009 (JP) 2009-119670

(51) Int. Cl. H03M 1/38

(52) U.S. Cl. 341/161

(57) ABSTRACT

Provided is an analog-digital converter circuit including: a comparison unit that sequentially compares an analog input voltage with reference voltages, which sequentially vary, and outputs a comparison result as a digital value; a standard voltage generation unit that generates a standard voltage for correcting the reference voltages; a storage unit that stores a comparison result of the standard voltage obtained by the comparison unit; and a reference voltage generation unit that generates the reference voltages based on the comparison result of the standard voltage.

### INCORPORATION BY REFERENCE

This application is based upon and claims the benefit of priority from Japanese patent application No. 2009-119670, filed on May 18, 2009, the disclosure of which is incorporated herein in its entirety by reference.

### BACKGROUND

1. Field of the Invention

The present invention relates to an analog-digital converter circuit and an analog-digital conversion method, and more particularly, to an analog-digital converter circuit and an analog-digital conversion method of a successive approximation type.

2. Description of Related Art

In general, successive approximation analog-digital converter circuits (A/D converters) include a comparator that sequentially compares an analog input voltage with a plurality of reference voltages determined according to a resolution (the number of bits). The reference voltages are generated using a power supply, for example, based on a predetermined digital value stored in a register or the like.

In the case of using a power supply, if the power supply voltage varies, the reference voltages, each of which is determined according to the predetermined digital value, also vary. This makes it difficult to perform an A/D conversion on the analog input voltage with accuracy. In particular, when a battery is used as the power supply, there arises a problem of a decrease in power supply voltage with the elapse of use time. Meanwhile, when a booster circuit such as a DC/DC converter is employed, for example, so that the standard voltage is held constant even when the power supply voltage varies, there arises another problem of an increase in cost. A technique for correcting an A/D conversion result of an analog input voltage while avoiding the problem of an increase in cost is disclosed in Japanese Unexamined Patent Application Publication No. 2005-26830.

FIG. 9 is a block diagram showing an A/D converter disclosed in FIG. 1 of Japanese Unexamined Patent Application Publication No. 2005-26830. The A/D converter includes a sensor 11, an A/D conversion unit 12, a microcomputer CPU 13 having the A/D conversion unit 12 mounted therein, a power supply 14, and a standard voltage generation unit 15. The standard voltage generation unit 15 generates a standard voltage for correcting a variation in the reference voltage of the A/D conversion unit 12 due to a variation in the voltage of the power supply 14. Then, an A/D conversion result of an analog input voltage from the sensor 11 is corrected using an A/D conversion result of the standard voltage for correction generated by the standard voltage generation unit 15.

FIG. 10 is a flowchart disclosed in FIG. 5 of Japanese Unexamined Patent Application Publication No. 2005-26830. Referring to FIG. 10, in the A/D converter disclosed in Japanese Unexamined Patent Application Publication No. 2005-26830, the standard voltage for correction is first subjected to A/D conversion and stored (step S1). Next, an output of the sensor 11 is subjected to A/D conversion (step S2). Then, the A/D conversion result obtained in step S2 is corrected using the A/D conversion result of the standard voltage stored in step S1 (step S3). Lastly, the corrected sensor output is used for a control operation (step S4).

### SUMMARY

The present inventor has found a problem as described below. That is, in the A/D converter disclosed in Japanese Unexamined Patent Application Publication No. 2005-26830, there are time constraints that the A/D conversion result cannot be used until a correction operation processing of step S3 is completed. In other words, there is a problem that the A/D converter disclosed in Japanese Unexamined Patent Application Publication No. 2005-26830 is not suitable for real time control which requires high-speed A/D conversion.

A first exemplary aspect of the present invention is an analog-digital converter circuit including: a comparison unit that sequentially compares an analog input voltage with a plurality of reference voltages and outputs a comparison result as a digital value; a standard voltage generation unit that generates a standard voltage for correcting the reference voltages; a storage unit that stores a comparison result of the standard voltage obtained by the comparison unit; and a reference voltage generation unit that generates the reference voltages corrected based on the comparison result of the standard voltage.

A second exemplary aspect of the present invention is an analog-digital conversion method including: converting a standard voltage into a digital value, the standard voltage being substantially constant independent of a variation of a power supply voltage; generating a plurality of reference voltages corrected based on a comparison result of the standard voltage; and sequentially comparing the plurality of reference voltages with an analog input voltage and converting the plurality of reference voltages into digital values.

According to the exemplary aspects of the present invention, the reference voltages corrected based on the A/D conversion result of the standard voltage are compared with the analog input signal. Therefore, the conversion result of the analog input signal can be directly used for a control operation.

According to the exemplary aspects of the present invention, it is possible to provide an analog-digital converter circuit and an analog-digital conversion method which are suitable for real time control.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing an analog-digital converter circuit according to a first exemplary embodiment of the present invention;

FIG. 2 is a diagram specifically showing a reference voltage generation circuit 104;

FIG. 3 is a flowchart showing a correction method according to an exemplary embodiment of the present invention;

FIG. 4 is a schematic diagram showing a comparison between an A/D conversion carried out when a power supply voltage VDD is normal and an A/D conversion carried out when the power supply voltage VDD decreases in a typical A/D converter;

FIG. 5 is a table showing an A/D conversion process carried out when the power supply voltage is normal (VDD=3.2 V);

FIG. 6 shows an A/D conversion process carried out when the power supply voltage decreases (VDD=2.2 V);

FIG. 7 is a conceptual diagram showing a correction method according to an exemplary embodiment of the present invention;

FIG. 8 is a table showing an A/D conversion process according to an exemplary embodiment of the present invention when the power supply decreases (VDD=2.2 V);

FIG. 9 is a block diagram showing an A/D converter disclosed in FIG. 1 of Japanese Unexamined Patent Application Publication No. 2005-26830; and

FIG. 10 is a flowchart disclosed in FIG. 5 of Japanese Unexamined Patent Application Publication No. 2005-26830.

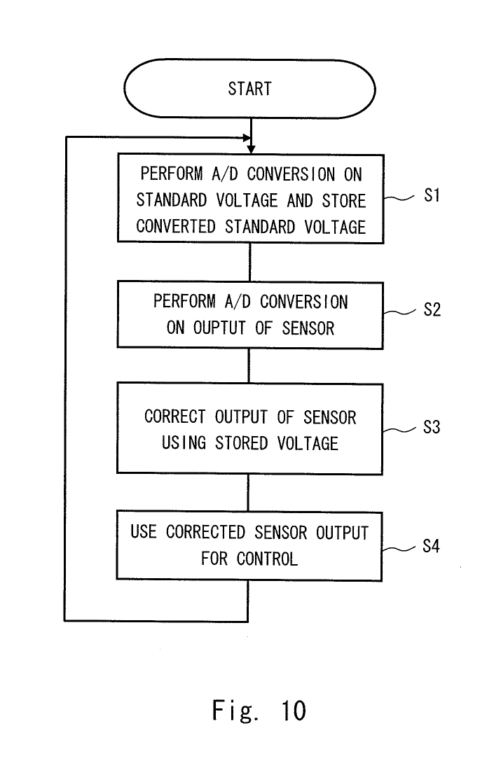

### DETAILED DESCRIPTION OF THE EXEMPLARY EMBODIMENTS

Exemplary embodiments of the present invention will be described in detail below with reference to the accompanying drawings. Note that the present invention is not limited to exemplary embodiments described below. The following description and the accompanying drawings are appropriately simplified to clarify the explanation.

### First Exemplary Embodiment

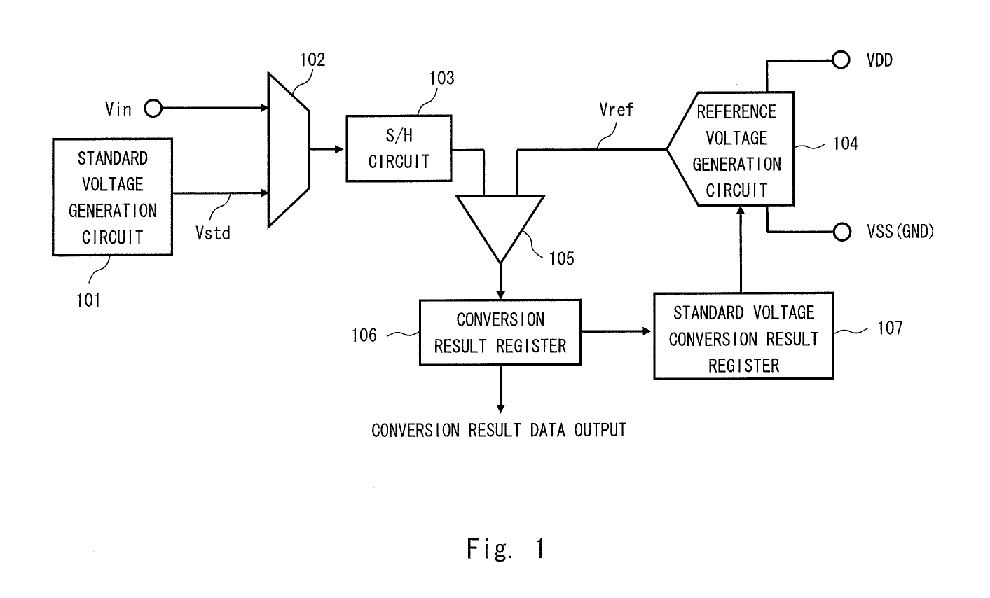

FIG. 1 is a block diagram showing an analog-digital converter circuit (hereinafter, referred to as “A/D converter”) according to a first exemplary embodiment of the present invention. The A/D converter includes a standard voltage generation circuit 101 for correction, a selector 102, a sample-and-hold (S/H) circuit 103, a reference voltage generation circuit 104, a comparator (comparison unit) 105, a conversion result register 106, and a standard voltage conversion result register 107.

The standard voltage generation circuit 101 generates and outputs a standard voltage Vstd for correction which is constant independently of a variation in power supply voltage. The selector 102 selects and outputs one of an analog input voltage Vin and the standard voltage Vstd output from the standard voltage generation circuit 101. The S/H circuit 103 samples the analog input voltage Vin or the standard voltage Vstd (hereinafter, referred to as “compared voltage”) output from the selector 102 to be compared in the comparator 105, and holds the voltage constant. The S/H circuit 103 is composed of, for example, a switch, which turns on and off in response to a clock signal, and a sampling capacitor.

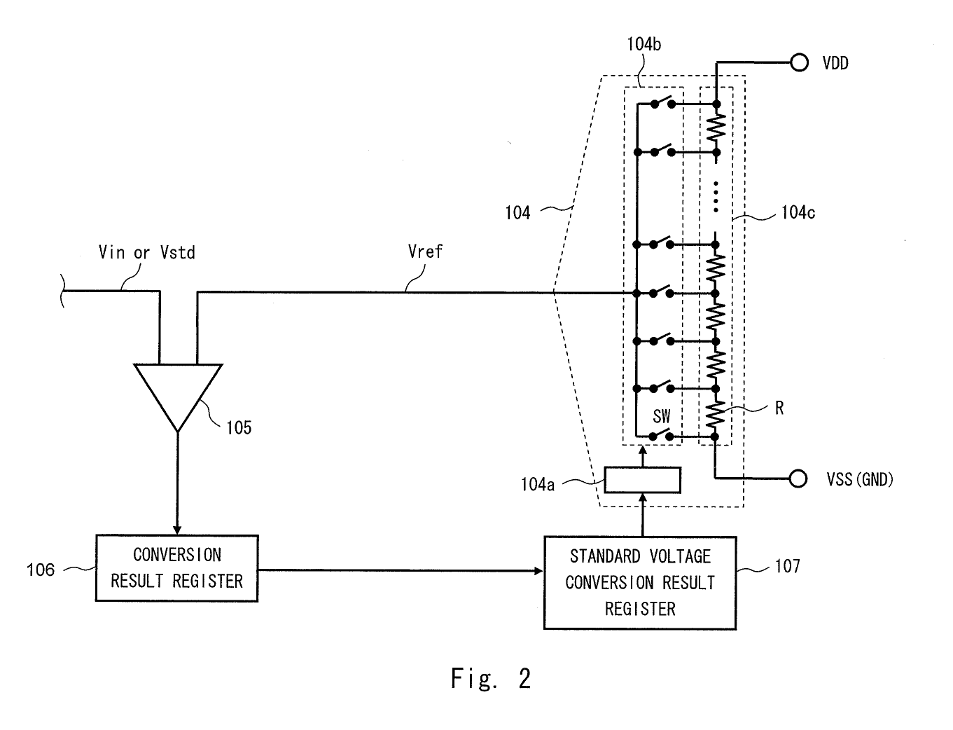

The reference voltage generation circuit 104 generates a digital signal for generating a reference voltage Vref based on an A/D conversion result of the standard voltage Vstd stored in the standard voltage conversion result register 107, and further generates the reference voltage Vref based on the digital signal. The reference voltage generation circuit 104 has a high-voltage side power supply terminal supplied with a power supply voltage VDD, and a low-voltage side power supply terminal supplied with a ground voltage GND. That is, the reference voltage generation circuit 104 generates the reference voltages Vref in the range from the ground voltage GND to the power supply voltage VDD. The reference voltage generation circuit 104 will be described in detail below with reference to FIG. 2.

The comparator 105 sequentially compares the compared voltage held in the S/H circuit 103 with the plurality of reference voltages Vref output from the reference voltage generation circuit 104, and outputs a comparison result as a digital signal. The conversion result register 106 temporarily stores and outputs the A/D conversion result output from the comparator 105. The standard voltage conversion result register 107 stores the A/D conversion result of the standard voltage Vstd.

FIG. 2 specifically shows the reference voltage generation circuit 104. Referring to FIG. 2, the reference voltage generation circuit 104 includes a digital signal generation circuit 104a, a tap selector 104b, and a series resistor string 104c.

The digital signal generation circuit 104a generates and outputs digital signals respectively corresponding to the reference voltages Vref based on the A/D conversion result of the standard voltage Vstd. The tap selector 104b includes a plurality of switches SW connected in parallel with each other. Turning on/off of each of the switches SW is controlled by the digital signal output from the digital signal generation circuit 104a.

The series resistor string 104c is formed of a plurality of resistors R connected in series with each other. One end of the series resistor string 104c is supplied with the power supply voltage VDD, and the other end thereof is supplied with the ground voltage GND. One end of each of the switches SW of the tap selector 104b is connected to an end of the series resistor string 104c or a node between two adjacent resistors R. The other end of each of the switches SW is commonly connected to an output of the reference voltage generation circuit 104.

That is, the tap selector 104b and the series resistor string 104c constitute a digital-analog converter circuit (D/A converter) of a resistor string type. With this configuration, the reference voltages Vref respectively corresponding to the digital signals, which are generated by the digital signal generation circuit 104a based on the A/D conversion result of the standard voltage Vstd, is output from the reference voltage generation circuit 104.

As described above, in a typical A/D converter, when the power supply voltage VDD varies, the reference voltages Vref, each of which is determined according to a predetermined digital value, also varies. This makes it difficult to perform an A/D conversion for the analog input voltage Vin with accuracy.

Meanwhile, even if the power supply voltage VDD varies, the A/D converter according to this exemplary embodiment can generate the reference voltage Vref equal to that obtained at the normal power supply voltage VDD, by use of the A/D conversion result of the standard voltage Vstd. In other words, the A/D converter according to this exemplary embodiment performs a correction operation so that the reference voltage Vref becomes equal to that obtained at the normal power supply voltage VDD, by use of the A/D conversion result of the standard voltage Vstd. The A/D conversion result equal to that obtained at the normal power supply voltage VDD can be obtained, because the analog input voltage Vin is compared with the reference voltage Vref equal to that obtained at the normal power supply voltage VDD. That is, it is possible to perform an A/D conversion on the analog input voltage Vin with accuracy. Further, the A/D conversion result can be directly used for a control operation, and thus the A/D converter according to this exemplary embodiment is suitable for real time control.

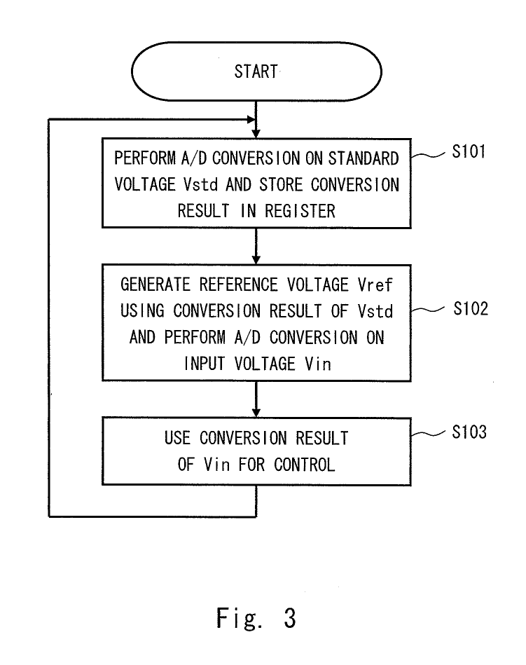

Referring next to FIG. 3, an outline of a correction method according to this exemplary embodiment will be described. FIG. 3 is a flowchart showing the correction method according to this exemplary embodiment. As shown in FIG. 3, according to the correction method of this exemplary embodiment, the standard voltage Vstd is first subjected to A/D conversion by the comparator 105 using the reference voltage Vref, which is not corrected yet, and the conversion result is stored in the standard voltage conversion result register 107 (S101).

Next, the reference voltage Vref is generated using the A/D conversion result of the standard voltage Vstd stored in the standard voltage conversion result register 107, and the analog input voltage Vin is subjected to A/D conversion (S102). In this case, the digital signal generation unit 104a generates a digital signal corresponding to the reference voltage Vref based on the A/D conversion result of the standard voltage Vstd so that the value of the reference voltage Vref becomes equal to that obtained at the normal power supply voltage VDD. The tap selector 104b and the series resistor string 104c convert the digital signal into the reference voltage Vref. Then, the comparator 105 compares the reference voltage Vref with the analog input voltage Vin.

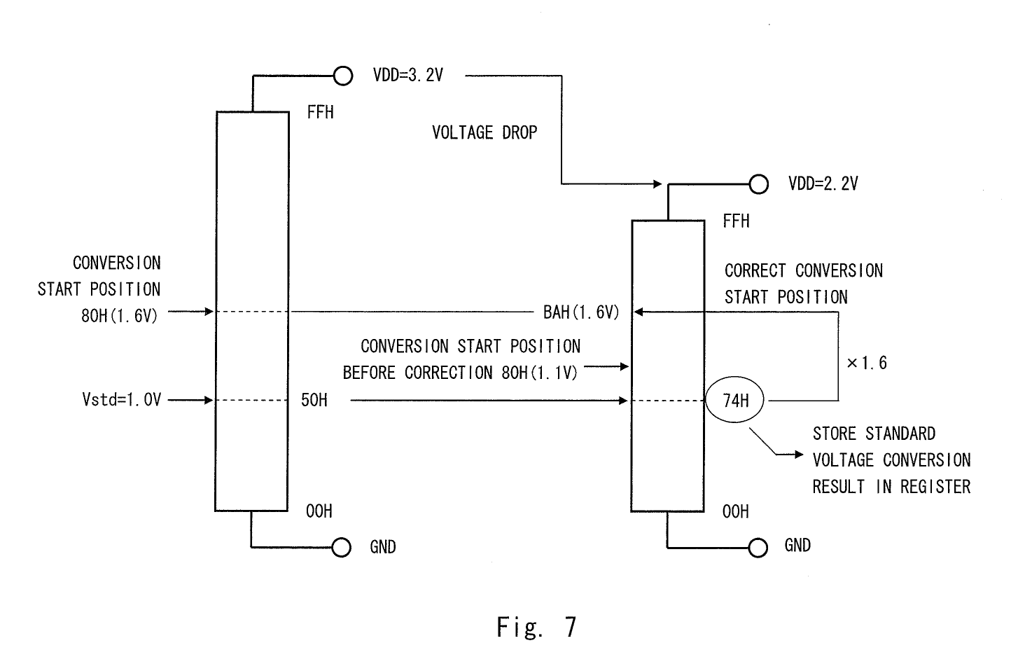

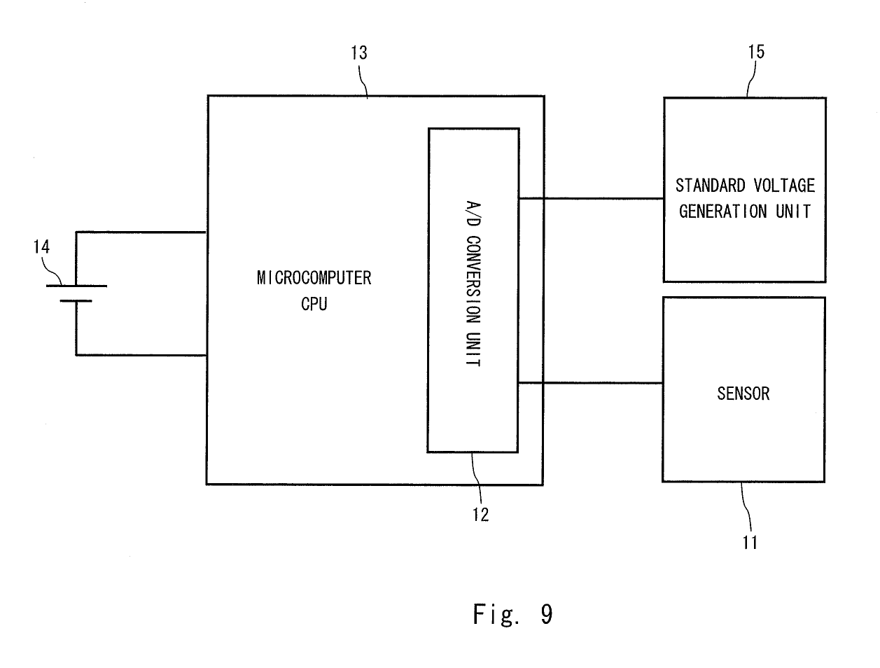

Lastly, the A/D conversion result of the analog input voltage Vin is used for a control operation (S103). The correction method will be described in detail later by way of a specific example with reference to FIGS. 7 to 9.

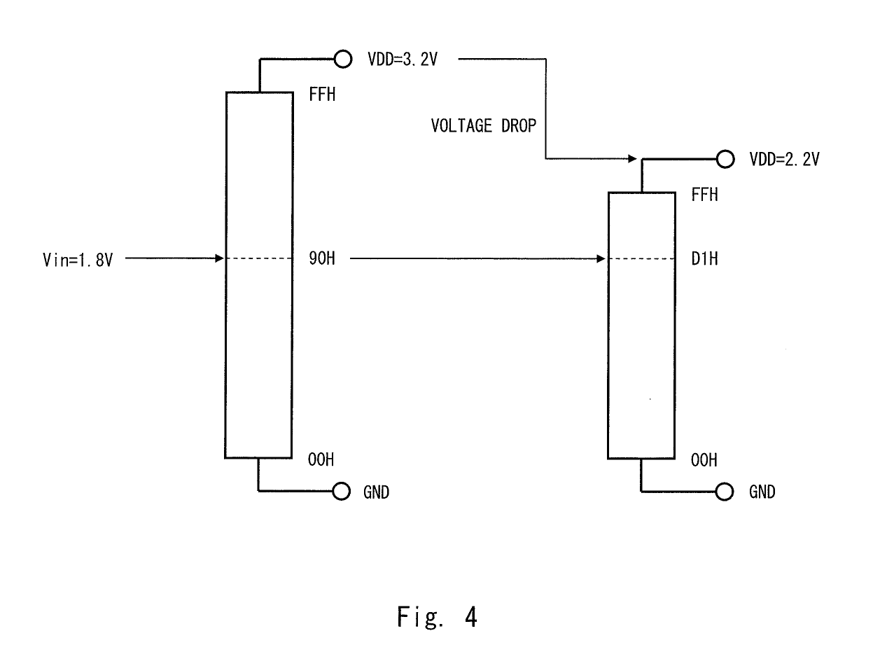

Next, a more specific example of the A/D conversion will be described. FIG. 4 is a schematic diagram showing a comparison between an A/D conversion carried out when the power supply voltage VDD is normal and an A/D conversion carried out when the power supply voltage VDD decreases in a typical A/D converter. The left side of FIG. 4 shows a case where the power supply voltage VDD is 3.2 V, which is a normal voltage, and the right side of FIG. 4 shows a case where the power supply voltage VDD decreases to 2.2 V. This assumes that two batteries each having a voltage of 1.6 V at the beginning of use decrease to 1.1 V at the end of use.

As shown on the left side of FIG. 4, when an analog input voltage Vin of 1.8 V (Vin=1.8 V) is subjected to A/D conversion with an 8-bit resolution (2⁸=256 levels) at a power supply voltage VDD of 3.2 V (VDD=3.2 V), the conversion result is represented by 1.8/3.2×256=144. This corresponds to 90H in hexadecimal notation represented by OOH to FFH. Meanwhile, as shown on the right side of FIG. 4, when the power supply voltage VDD decreases to 2.2 V, the conversion result for the same analog input voltage Vin of 1.8 V (Vin=1.8 V) is represented by 1.8/2.2×256≈209 which corresponds to D1H in hexadecimal notation. In this way, when the power supply voltage VDD varies, the A/D conversion results for the same analog input voltage Vin show different values.

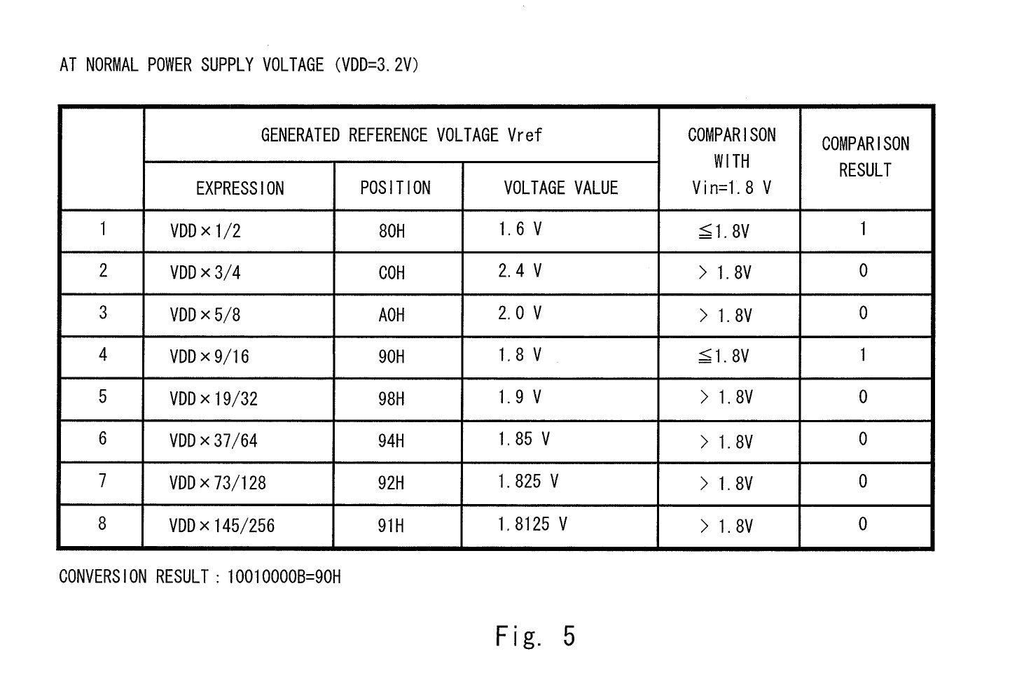

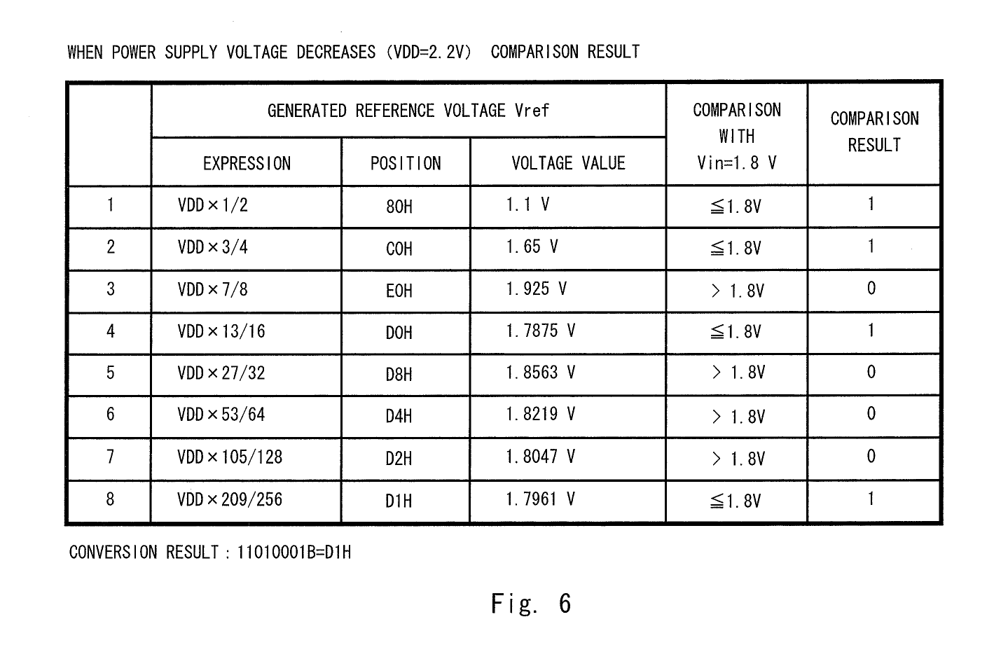

Referring now to FIGS. 5 and 6, the reasons therefor will be described in detailed. FIG. 5 is a table showing an A/D conversion process at a normal power supply voltage (VDD=3.2 V). Specifically, FIG. 5 shows an A/D conversion process illustrated on the left side of FIG. 4. Since the A/D conversion is performed with an 8-bit resolution, a comparison is carried out eight times to generate the reference voltages Vref respectively corresponding to the comparison results.

As shown in FIG. 5, in a first comparison, the reference voltage Vref to be generated is given by an expression of VDD×1/2. In this case, 1/2=128/256 is obtained, so a reference voltage Vref=1.6 V is generated based on a digital value 128=80H. Further, the reference voltage Vref is compared with the analog input voltage Vin, and Vref=1.6V≦Vin=1.8 V is established, so that the comparison result shows “1”.

Since the first comparison result shows “1”, the reference voltage Vref in a second comparison is given by an intermediate value between VDD and VDD×1/2, i.e., an expression of VDD×3/4. In this case, 3/4=192/256 is obtained, so a reference voltage Vref=2.4 V is generated based on a digital value VOH. Further, Vref=2.4 V>Vin=1.8 V is established, so that the comparison result shows “0”.

Since the second comparison result shows “0”, the reference voltage Vref in a third comparison is given by an intermediate value between VDD×1/2 and VDD×3/4, i.e., an expression of VDD×5/8. In this case, 5/8=160/256 is obtained, so a standard voltage=2.0 V is generated based on a digital value AOH. Further, Vref=2.0 V>Vin=1.8 V is established, so that the comparison result shows “0”.

Since the third comparison result shows “0”, the reference voltage Vref in a fourth comparison is given by an intermediate value between VDD×1/2 and VDD×5/8, i.e., an expression of VDD×9/16. In this case, 9/16=114/256 is obtained, so a reference voltage Vref=1.8 V is generated based on a digital value 90H. Further, Vref=1.8 V≦Vin=1.8 V is established, so that the comparison result shows “1”.

Since the fourth comparison result shows “1”, the reference voltage Vref in a fifth comparison is given by an intermediate value between VDD×9/16 and VDD×5/8, i.e., an expression of VDD×19/32. In this case, 19/32=152/256 is obtained, so a standard voltage of 1.9 V is generated based on a digital value 98H. Further, Vref=1.9 V>Vin=1.8 V is established, so that the comparison result shows “0”.

Since the fifth comparison result shows “0”, the reference voltage Vref in a sixth comparison is given by an intermediate value between VDD×9/16 and VDD×19/32, i.e., an expression of VDD×37/64. In this case, 37/64=148/256 is obtained, so a reference voltage Vref=1.85 V is generated based on a digital value 94H. Further Vref=1.85 V>Vin=1.8 V is established, so that the comparison result shows “0”.

Since the sixth comparison result shows “0”, the reference voltage Vref in a seventh comparison is given by an intermediate value between VDD×9/16 and VDD×37/64, i.e., an expression of VDD×73/128. In this case, 73/128=146/256 is obtained, so a reference voltage Vref=1.825 V is generated based on a digital value 92H. Further, Vref=1.825 V>Vin=1.8 V is established, so that the comparison result shows “0”.

Since the seventh comparison result shows “0”, the reference voltage Vref in the last comparison, i.e., an eighth comparison, is given by an intermediate value between VDD×9/16 and VDD×73/128, i.e., an expression of VDD×145/256. In this case, 145/256 is obtained, so a reference voltage Vref=1.8125 V is generated based on a digital value 91H. Further, Vref=1.8125 V>Vin=1.8 V is established, so that the comparison result shows “0”. As a result, a value expressed as “10010000B” in binary notation, i.e., the digital value 90H in hexadecimal notation, is obtained.

Meanwhile, FIG. 6 is a table showing an A/D conversion process according to a comparative example of this exemplary embodiment when the power supply voltage decreases (VDD=2.2 V). Specifically, FIG. 6 shows an A/D conversion process illustrated on the right side of FIG. 4. In the first comparison, as with the case of FIG. 5, the reference voltage Vref to be generated is given by VDD×1/2 and 1/2=128/256 is obtained. Accordingly, the reference voltage Vref is generated based on the digital value 128=80H. In this case, however, since the power supply voltage VDD is 2.2 V, the generated reference voltage Vref is 1.1 V. Further, the reference voltage Vref is compared with the analog input voltage Vin, and Vref=1.1 V≦Vin=1.8 V is established, so that the comparison result shows “1”.

Since the first comparison result shows “1”, the reference voltage Vref in the second comparison is given by an intermediate value between VDD and VDD×1/2, i.e., an expression of VDD×3/4. In this case, 3/4=192/256 is obtained, so a reference voltage Vref=1.65 V is generated based on a digital value C0H. Further, Vref=1.65 V≦Vin=1.8 V is established, so that the comparison result shows “1”.

Since the second comparison result shows “1”, the reference voltage Vref in the third comparison is given by an intermediate value between VDD and VDD×3/4, i.e., an expression of VDD×7/8. In this case, 7/8=224/256 is obtained, so a reference voltage Vref=1.925 V is generated based on a digital value E0H. Further, Vref=1.925 V>Vin=1.8 V is established, so that the comparison result shows “0”.

Since the third comparison result shows “0”, the reference voltage Vref in the fourth comparison is given by an intermediate value between VDD×3/4 and VDD×7/8, i.e., an expression of VDD×13/16. In this case, 13/16=208/256 is obtained, so a reference voltage Vref=1.7875 V is generated based on a digital value DOH. Further, Vref=1.7875 V≦Vin=1.8 V is established, so that the comparison result shows “1”.

Since the fourth comparison result shows “1”, the reference voltage Vref in the fifth comparison is given by an intermediately value between VDD×13/16 and VDD×7/8, i.e., an expression of VDD×27/32. In this case, 27/32=216/256 is obtained, so a reference voltage Vref=1.8563 V is generated based on a digital value D8H. Further, Vref=1.8563 V>Vin=1.8 V is established, so that the comparison result shows “0”.

Since the fifth comparison result shows “0”, the reference voltage Vref in the sixth comparison is given by an intermediate value between VDD×13/16 and VDD×27/32, i.e., an expression of VDD×53/64. In this case, 53/64=212/256 is obtained, so a reference voltage Vref=1.8219 V is generated based on a digital value D4H. Further, Vref=1.8219 V>Vin=1.8 V is established, so that the comparison result shows “0”.

Since the sixth comparison result shows “0”, the reference voltage Vref in the seventh comparison is given by an intermediate value between VDD×13/16 and VDD×53/64, i.e., an expression of VDD×105/128. In this case, 105/128=210/256 is obtained, so a reference voltage Vref=1.8047 V is generated based on a digital value D2H. Further, Vref=1.8047 V>Vin=1.8 V is established, so that the comparison result shows “0”.

Since the seventh comparison result shows “0”, the reference voltage Vref in the last comparison, i.e., the eighth comparison, is given by an intermediate value between VDD×13/16 and VDD×105/128, i.e., an expression of VDD×209/256. In this case, 209/256 is obtained, so a reference voltage Vref=1.7961 V is generated based on a digital value D1H. Further, Vref=1.7961 V<Vin=1.8 V is established, so that the comparison result shows “1”. As a result, a value expressed as “11010001B” in binary notation, i.e., the digital value D1H in hexadecimal notation, is obtained.

As described above with reference to FIGS. 5 and 6, when the power supply voltage VDD varies, the generated reference voltage Vref also varies. As a result, the A/D conversion results for the same analog input voltage Vin show different values.

FIG. 7 is a conceptual diagram showing the correction method according to this exemplary embodiment. As with FIG. 4, the left side of FIG. 7 shows the case where the power supply voltage VDD is 3.2 V, which is a normal voltage, and the right side of FIG. 7 shows the case where the power supply voltage VDD decreases to 2.2 V. In this exemplary embodiment, as described above with reference to FIG. 3, the standard voltage Vstd, which remains constant independently of the variation of the power supply voltage VDD, is first subjected to A/D conversion.

Referring to FIG. 7, assuming that the standard voltage Vstd is 1.0 V (Vstd=1.0 V), for example, when the power supply voltage VDD is 3.2 V, which is a normal voltage, the conversion result is represented by 1.0/3.2×256=80, i.e., 50H in hexadecimal notation. Meanwhile, when the power supply voltage VDD decreases to 2.2 V, the conversion result is represented by 1.0/2.2×256=116, i.e., 74H in hexadecimal notation. Here, the A/D conversion processes are similar to those of FIGS. 5 and 6, so the description thereof is omitted. The A/D conversion result 74H of the standard voltage Vstd is stored in the standard voltage conversion result register 107.

As described in detail with reference to FIGS. 5 and 6 and as shown in FIG. 7, even when the power supply voltage VDD varies, a typical A/D conversion is always started from the same position, i.e., 80H. Specifically, as shown in FIG. 7, when the power supply voltage VDD is 3.2 V, which is a normal voltage, the reference voltage Vref at the start of the conversion, i.e., the first comparison, is 1.6 V. Meanwhile, when the power supply voltage VDD decreases to 2.2 V, the reference voltage Vref obtained in the first comparison is 1.1 V in the typical A/D conversion. In this exemplary embodiment, even when the power supply voltage VDD decreases to 2.2 V, a correction operation is performed so that the reference voltage Vref obtained in the first comparison becomes 1.6 V which is equal to that obtained at the normal power supply voltage VDD. In this case, the A/D conversion result of the standard voltage Vstd stored in the standard voltage conversion result register 107 is used.

Herein, a general expression for correcting a conversion start position is as follows.

(corrected conversion start position)=(Vstd conversion result)×(normal conversion start Vref)/Vstd

In an exemplary embodiment shown in FIG. 7, the A/D conversion result 74H at a standard voltage Vstd of 1.0 V is 116 (74H=116) and the normal conversion start Vref is 1.6 V (Vref=1.6 V). Accordingly, the corrected conversion start position is represented by 116×1.6/1.0=185.6, i.e., BAH in hexadecimal notation. On the basis of the digital value, the reference voltage Vref of 1.6 V, which is obtained in the first comparison and which is equal to that obtained at the normal power supply voltage VDD, can be generated.

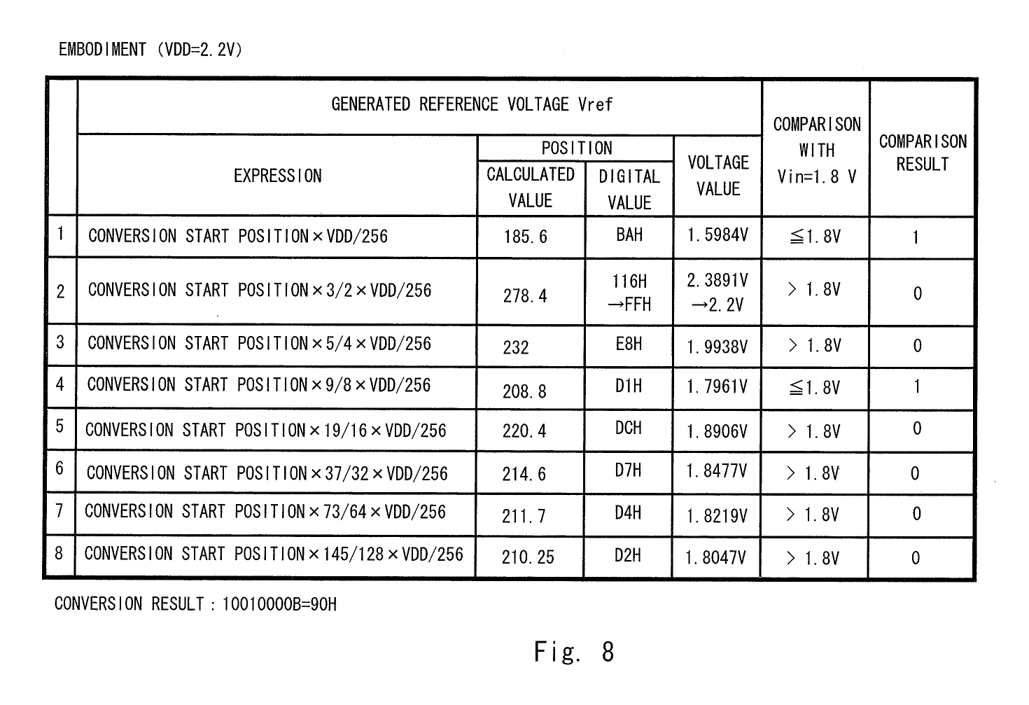

FIG. 8 is a table showing an A/D conversion process according to this exemplary embodiment when the power supply voltage decreases (VDD=2.2 V). As with the cases of FIGS. 5 and 6, the analog input voltage Vin is 1.8 V (Vin=1.8 V). As shown in FIG. 8, in the first comparison, the reference voltage Vref to be generated is given by an expression of (conversion start position)×VDD/256. In this case, as described above, a reference voltage Vref=1.5984 V is generated based on the conversion start position of 185.6, i.e., BAH. Further, the reference voltage Vref is compared with the analog input voltage Vin, and Vref=1.5984 V≦Vin=1.8 V is established, so that the comparison result shows “1”.

Since the first comparison result shows “1”, the position of the reference voltage Vref in the second comparison is given by an intermediate value between the conversion start position and (conversion start position)×2, i.e., (conversion start position)×3/2. In this case, (conversion start position)×3/2=185.6×3/2=278.4, so a digital value 116H is obtained. The digital value exceeds an 8-bit upper limit of FFH. For this reason, a reference voltage Vref=2.2 V is generated based on the FFH. In this case, Vref=2.2 V>Vin=1.8 V is established, so that the comparison result shows “0”.

Since the second comparison result shows “0”, the reference voltage Vref in the third comparison is given by an intermediate value between the conversion start position and (conversion start position)×3/2, i.e., (conversion start position)×5/4. In this case, (conversion start position)×5/4=185.6×5/4=232 is obtained, so a reference voltage Vref=1.9938 V is generated based on a digital value E8H. Further, Vref=1.9938 V>Vin=1.8 V is established, so that the comparison result shows “0”.

Since the third comparison result shows “0”, the reference voltage Vref in the fourth comparison is given by an intermediate value between the conversion start position and (conversion start position)×5/4, i.e., (conversion start position)×9/8. In this case, (conversion start position)×5/4=185.6×9/8=208.8 is obtained, so a reference voltage Vref=1.7961 V is generated based on the digital value D1H. Further, Vref1.7961 V≦Vin=1.8 V is established, so that the comparison result shows “1”.

Since the fourth comparison result shows “1”, the reference voltage Vref in the fifth comparison is given by an intermediate value between (conversion start position)×9/8 and (conversion start position)×5/4, i.e., (conversion start position)×19/16. In this case, (conversion start position)×19/16=185.6×19/16=220.4 is obtained, so a reference voltage Vref=1.8906 V is generated based on a digital value DCH. Further, Vref=1.8906 V>Vin=1.8 V is established, so that the comparison result shows “0”.

Since the fifth comparison result shows “0”, the reference voltage Vref in the sixth comparison is given by an intermediate value between (conversion start position)×9/8 and (conversion start position)×19/16, i.e., (conversion start position)×37/32. In this case, (conversion start position)×37/32=185.6×37/32=214.6 is obtained, so a reference voltage Vref=1.8477 V is generated based on a digital value D7H. Further, Vref=1.8477 V>Vin=1.8 V is established, so that the comparison result shows “0”.

Since the sixth comparison result shows “0”, the reference voltage Vref in the seventh comparison is given by an intermediate value between (conversion start position)×9/8 and (conversion start position)×37/32, i.e., (conversion start position)×73/64. In this case, (conversion start position)×73/64=185.6×73/64=211.7, so a reference voltage Vref=1.8219 V is generated based on the digital value D4H. Further, Vref=1.8219 V>Vin=1.8 V is established, so that the comparison result shows “0”.

Since the seventh comparison result shows “0”, the reference voltage Vref in the last comparison, i.e., the eighth comparison, is given by an intermediate value between (conversion start position)×9/8 and (conversion start position)×73/64, i.e., (conversion start position)×145/128. In this case, (conversion start position)×145/128=185.6×145/128=210.25 is obtained, so a reference voltage Vref=1.8047 V is generated based on the digital value D2H. Further, Vref=1.8047 V>Vin=1.8 V is established, so that the comparison result shows “0”. As a result, a value expressed as “10010000B” in binary notation, i.e., the digital value 90H in hexadecimal notation, is obtained. That is, the A/D conversion result equal to that obtained at the normal power supply voltage VDD of 3.2 V can be obtained.

As described above, in the A/D converter according to this exemplary embodiment, even when the power supply voltage VDD varies, the reference voltage Vref equal to that obtained at the normal power supply voltage VDD is generated by the use of the A/D conversion result of the standard voltage Vstd. In other words, a correction process is performed using the A/D conversion result of the standard voltage Vstd so that the reference voltage Vref becomes equal to that obtained at the normal power supply voltage VDD. The analog input voltage Vin is compared with the reference voltage Vref which is equal to that obtained at the normal power supply voltage VDD, thereby making it possible to obtain the same A/D conversion result as that obtained at the normal power supply voltage VDD. In other words, the analog input voltage Vin can be subjected to A/D conversion with accuracy. Moreover, the A/D converter according to this exemplary embodiment is suitable for real time control, because the A/D conversion result can be directly used for a control operation.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An analog-digital converter circuit comprising:
a comparison unit that sequentially compares an analog input voltage with a plurality of reference voltages and outputs a comparison result as a digital value;
a standard voltage generation unit that generates a standard voltage for correcting the reference voltages;
a storage unit that stores a comparison result of the standard voltage obtained by the comparison unit; and
a reference voltage generation unit that generates the reference voltages corrected based on the comparison result of the standard voltage.

2. The analog-digital converter circuit according to claim 1, wherein the reference voltages are generated from a power supply voltage.

3. The analog-digital converter circuit according to claim 2, wherein the standard voltage is substantially constant independently of a variation of the power supply voltage.

4. The analog-digital converter circuit according to claim 2, wherein the reference voltage generation unit generates the reference voltages, the reference voltages being substantially constant independently of a variation of the power supply voltage.

5. The analog-digital converter circuit according to claim 1, wherein the reference voltage generation unit comprises:
a digital signal generation circuit that generates digital signals respectively corresponding to the reference voltages based on the comparison result of the standard voltage; and
a digital-analog converter circuit that converts the digital signals into the reference voltages.

6. The analog-digital converter circuit according to claim 5, wherein the digital-analog converter circuit is a resistor string type digital-analog converter circuit.

7. An analog-digital conversion method comprising:
converting a standard voltage into a digital value, the standard voltage being substantially constant independent of a variation of a power supply voltage;
generating a plurality of reference voltages corrected based on a comparison result of the standard voltage; and
sequentially comparing the plurality of reference voltages with an analog input voltage and converting the analog input voltage into a digital value.

8. The analog-digital conversion method according to claim 7, wherein the reference voltages are generated from the power supply voltage.

9. The analog-digital conversion method according to claim 7, wherein the reference voltages substantially constant independently of the variation of the power supply voltage are generated.

10. The analog-digital conversion method according to claim 7, wherein the generating the plurality of reference voltages includes:
generating digital signals respectively corresponding to the reference voltages based on the comparison result of the standard voltage; and
converting the digital signals into the reference voltages.
